(19) United States
(12) Patent Application Publication
(10) Pub. No.: US 2006/0189074 A1
(43) Pub. Date: Aug. 24, 2006

(54) STRUCTURE CONTAINING SELF-ALIGNED CONDUCTIVE LINES AND FABRICATING METHOD THEREOF

(76) Inventors: Hann-Jye Hsu, Taichung County (TW); Su-Yuan Chang, Hsinchu Hsien (TW); Min-San Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,077

(22) Filed: Aug. 29, 2005

(30) Foreign Application Priority Data
Feb. 18, 2005 (TW) 94104794

(51) Int. Cl. H01L 21/336; H01L 29/76

(52) U.S. Cl. 438/257; 257/314

(57) ABSTRACT

A method for fabricating self-aligned conductive lines is provided. A substrate with a plurality of isolation structures is provided. The isolation structures are protrusive from the surface of the substrate, and an active region is defined between two adjacent isolation structures. A plurality of semiconductor devices is formed in the active region. A conductive material layer is then formed on the substrate. Thereafter, a portion of the conductive material layer is removed by using the isolation structures as a removing-stop layer until the surfaces of the isolation structures are exposed and a plurality of conductive lines are formed in a self-aligned manner to electrically connect devices. As the size of the devices is scaled down, the design rule of the lithography process does not limit the size of self-aligned conductive lines. Consequently, the fabricated conductive lines are capable of effectively connecting the semiconductor devices.

### CROSS-REFERENCE TO RELATED APPLICATION

This application claims the priority benefit of Taiwan application serial no. 941 04794, filed on Feb. 18, 2005. All disclosure of the Taiwan application is incorporated herein by reference.

### BACKGROUND OF THE INVENTION

1. Field of Invention

The present invention relates to a semiconductor device and a semiconductor process. In particular, the present invention relates to a structure containing self-aligned conductive lines and a fabricating method thereof.

2. Description of the Prior Art

The modern semiconductor industry fabricate many electronic devices and conductive lines inside a substrate of silicon wafer by semiconductor processes. Thanks to the process of lithography and etching introduced into the semiconductor industry, it is now possible to scale down many electronic devices and conductive lines and fabricate them on a silicon wafer to produce semiconductor devices with various functions.

In any process for fabricating memory cells on a silicon wafer, after the fabrication, it is necessary to further fabricate conductive lines (word lines) to connect each memory cell to make the cells operate properly.

FIG. 1A is a schematic top view of a flash memory array. In FIG. 1A, isolation structures 110 in the flash memory array are formed in bar layout. The isolation structures 110 serve to define active regions 120 in which a plurality of memory cells have been formed previously (not shown). Conductive lines (word lines) 140a have been fabricated on the active regions 120 and electrically connected to individual memory cells. The conductive lines 140a are conventionally fabricated by means of the lithography etching process.

FIGS. 1B and 1C are schematic cross-sectional views of a process of fabricating the conductive line along line A-A′ in FIG. 1A. Referring to both FIGS. 1B and 1C, as shown in FIG. 1B, a plurality of isolation structures 110 in bar layout have been formed previously in the substrate 100. The active regions 120 are defined between two adjacent isolation structures 110. In addition, a plurality of memory cell devices have already been formed in the active regions (not shown). As the isolation structures 110 were formed, a remaining pad oxide layer 130 covered the active regions 120. At this point, to avoid short circuit between devices in different layers in case no voltage is applied, it is necessary to form an interlayer dielectric (ILD) 135 on the active regions 120. Further, the conductive lines and the other device structures are then fabricated on the interlayer dielectric 135.

In general, to fabricate the conductive lines 140a on the interlayer dielectric 135, first, a conductive material layer 140 is entirely formed on the substrate 100. The formed conductive material layer 140 covers the isolation structures 110, the active regions 120, and the interlayer dielectric 135. Then, a patterned photoresistive layer 150 is formed on the conductive material layer 140. Further, taking the patterned photoresistive layer 150 as an etching mask and by means of the dry etching process 160, the conductive material layer 140 and the interlayer dielectric 135 are etched to fabricate a patterned interlayer dielectric (patterned ILD) 135a and individual conductive lines (word lines) 140a for connecting each memory cell array.

However, the following problems have occurred in the above-described process of lithography etching to fabricate the conductive lines 140a. First, the wavelength of exposure light limits the size of the conductive line 140a. Along with the enhanced integration of devices and the trend for even smaller memory cells to be fabricated, thinner conductive lines 140a certainly will be encountered. To fabricate a thinner conductive line 140a, the wavelength of the exposure light must be shortened. However, any bottleneck caused by the optical design rule of the lithography process can limit infinitely the wavelength of exposure light. Therefore, it is difficult to fabricate the conductive line 140a with the required thinner size.

In addition, the accuracy of the pattern of conductive lines 140a defined by a lithography process is affected by exposure accuracy. Namely, if the position of the exposure mask or the angle of the exposure light is inaccurate, the position of the exposure pattern also accordingly deviates, affecting the position accuracy of the formed conductive lines 140a. Consequently, the electric connections between different devices can be adversely affected, even to the extent of failing to work properly.

### SUMMARY OF THE INVENTION

The object of the present invention is to provide a structure containing self-aligned conductive lines and a fabricating method thereof, suitable for fabricating conductive lines with thinner size and higher position accuracy.

Based on the above-mentioned object or other objects, the present invention provides a method for fabricating self-aligned conductive lines. First, a substrate is provided. In the substrate, a plurality of isolation structures have been formed previously. These isolation structures are protrusive from the surface of the substrate. Between the adjacent isolation structures, an active region is defined, and a plurality of devices is formed in the active regions, previously. Further, a conductive material layer to cover the isolation structures and the active regions is formed on the substrate. Thereafter, a portion of the conductive material layer is removed, using the isolation structures as removing-stop layers until the surfaces of the isolation structures are exposed, such that a plurality of conductive lines is formed on the active regions in a self-aligned manner to electrically connect the devices.

According to the method for fabricating self-aligned conductive lines described in the embodiment of the present invention, the above-mentioned conductive material layer is made of, for example, poly silicon or metal.

According to the method for fabricating self-aligned conductive lines described in the embodiment of the present invention, the method for fabricating the above-mentioned conductive material layer includes physical vapor deposition (PVD) and chemical vapor deposition (CVD).

According to the method for fabricating self-aligned conductive lines described in the embodiment of the present invention, the method for removing the above-mentioned portion of conductive material layer is chemical mechanical polishing (CMP) or etching-back.

According to the method for fabricating self-aligned conductive lines described in the embodiment of the present invention, the above-mentioned conductive lines are a plurality of word lines (WLs) in the memory array, for example.

According to the method for fabricating self-aligned conductive lines described in the embodiment of the present invention, the method for forming the above-mentioned isolation structures is, for example, shallow trench isolation process.

According to the method for fabricating self-aligned conductive lines described in the embodiment of the present invention, the semiconductor devices are trench devices, for example.

According to the method for fabricating self-aligned conductive lines described in the embodiment of the present invention, each of the trench devices include, for example, a tunnel oxide layer, a control gate, two floating gates, and a dielectric layer. The tunnel oxide layer is formed on the surface of a trench in the active region. The two floating gates are formed on both sides of the control gate. The dielectric layer is formed between the control gate and the two floating gates, and covering them.

According to the method for fabricating self-aligned conductive lines described in the embodiment of the present invention, the above-mentioned trench devices further include a buried bit line disposed in the substrate of the trench, and a control gate located over the buried bit line.

The present invention further provides a structure containing self-aligned conductive lines. The structure includes a substrate, a plurality of isolation structures, and a conductive line. The isolation structures are located in the substrate, and each of the isolation structures has a protrusion which is protrusive from the substrate surface. A gap is formed between two protrusions, and between the adjacent isolation structures an active region is defined. The active region has a plurality of devices. The conductive lines are located in the gaps, covering over the active regions, and electrically connect a plurality of devices. The surfaces of the conductive lines are of the same height as the top surfaces of isolation structures.

According to the structure containing the self-aligned conductive lines described in the embodiment of the present invention, the above-mentioned conductive lines are made of, for example, poly silicon or metal.

According to the structure containing self-aligned conductive lines described in the embodiment of the present invention, the above-mentioned devices include, for example, a plurality of semiconductor devices, and the semiconductor devices are trench devices, for example.

The present invention provides a semiconductor structure which includes a substrate, a plurality of trench devices, a plurality of isolation structures, and a conductive line. The isolation structures are located in the substrate, and each of the isolation structures has a protrusion which is protrusive from the substrate surface. A gap is formed between two protrusions, and an active region is defined between the adjacent isolation structures. The trench devices are located in the active region. Each of the trench devices includes a tunnel oxide layer, a control gate, two floating gates, and a dielectric layer. The tunnel oxide layer is disposed on the surface of a trench in the active region. The two floating gates are disposed on both sides of the control gate. The dielectric layer is located between the control gate and the two floating gates, and covering them. The conductive lines are located in the gaps, covering over the active regions, and electrically connect a plurality of the trench devices. The surfaces of the conductive lines are of the same height as the top surfaces of the isolation structures.

According to the semiconductor structure described in the embodiment of the present invention, the above-mentioned conductive line is a word line.

According to the semiconductor structure described in the embodiment of the present invention, the above-mentioned isolation structures are shallow trench isolation (STI) structures.

According to the semiconductor structure described in the embodiment of the present invention, the above-mentioned trench devices further include, for example, a source/drain region located in the substrate of the trench and below the control gate.

According to the semiconductor structure described in the embodiment of the present invention, the above-mentioned trench device further includes, for example, a buried bit line located in the substrate of the trench and below the control gate.

The present invention uses isolation structures previously formed on the substrate to define the active regions. The present invention takes the isolation structures protruding from the substrate as the removing-stop layer and deposits an entire layer of conductive material on the substrate, then removes a portion of the conductive material layer until the surfaces of the isolation structures are exposed. In this way, a plurality of the conductive lines is formed on the active region in a self-aligned manner to electrically connect the semiconductor devices. The method provided by the present invention is suitable for fabricating self-aligned conductive lines with thinner size and higher position accuracy.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve in explaining the principles of the invention.

FIG. 1A is a schematic top view of a flash memory array.

FIGS. 1B and 1C are schematic cross-sectional views of a process of fabricating the conductive line along line A-A′ in FIG. 1A.

FIGS. 2A-2C are schematic cross-sectional views of a process of fabricating self-aligned conductive lines along line A-A′ in FIG. 1A in an embodiment of the present invention.

FIG. 2D schematically shows a structure containing self-aligned conductive lines in another embodiment of the present invention.

FIG. 3A is a schematic top view of an array containing trench devices.

FIG. 3B is a schematic cross-sectional view showing a process of fabricating the word line along line B-B′ in the process for fabricating an array containing trench devices.

### DESCRIPTION OF THE EMBODIMENTS

### The First Embodiment

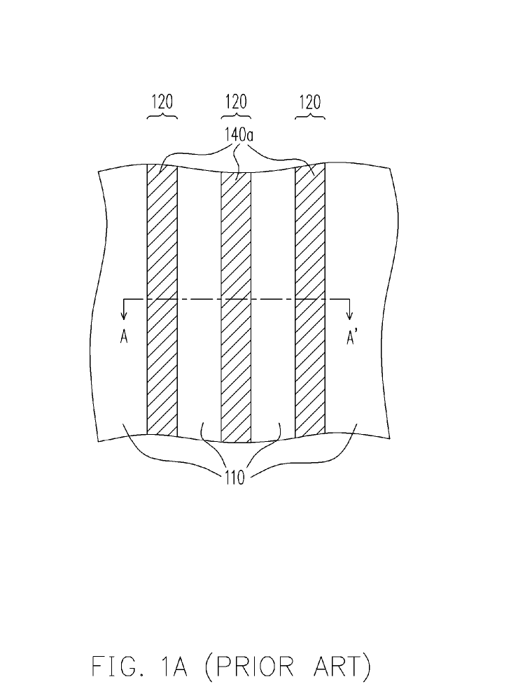

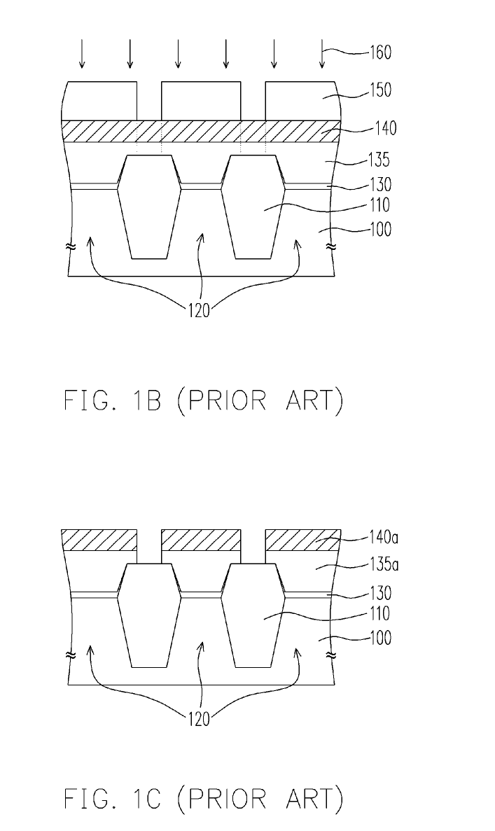

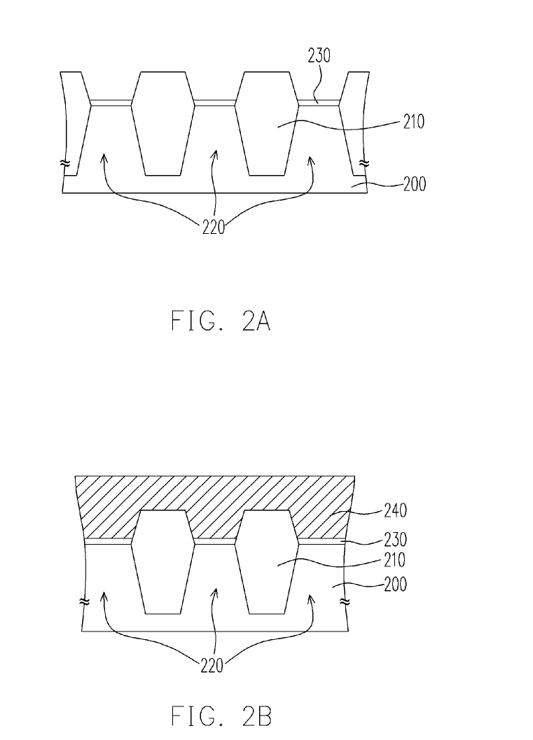

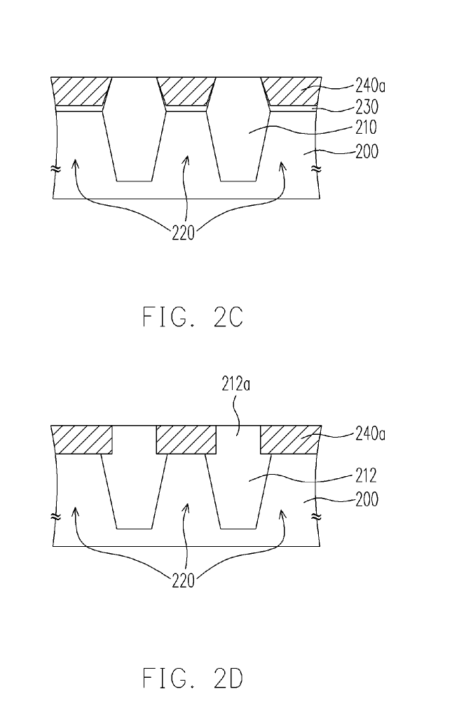

FIGS. 2A-2C are schematic cross-sectional views of a process of fabricating self-aligned conductive lines along line A-A′ in FIG. 1A in an embodiment of the present invention. Please refer to FIGS. 2A-2C.

Referring to FIG. 2A, first the substrate 200 is provided. A plurality of isolation structures 210 previously formed in the substrate 200 are protrusive from the surface of substrate 200. An active region 220 is defined between the adjacent isolation structures 210. In the active region 220, a plurality of devices have been formed previously (not shown). The isolation structures 210 are much higher than the devices. In an embodiment, the isolation structures 210 are in bar layout, and the fabricating method thereof is, for example, shallow trench isolation (STI) process. The active region 220 is defined between the isolation structures 210 in bar layout. In the active region 220, a plurality of semiconductor devices are trench devices, for example (not shown).

In addition, a pad oxide layer 230 is located on the substrate 200 and covers the active regions 220. The pad oxide layer 230 provides an increased adherence between the conductive material layer 240 and the substrate 200.

Continuing next to FIG. 2B, a conductive material layer 240 is formed on the substrate 200 to cover the isolation structures 210 and the active regions 220. In an embodiment, the conductive material layer 240 is made of, for example, poly silicon or metal. The method for forming the conductive material layer 240 is, for example, physical vapor deposition (PVD) or chemical vapor deposition (CVD).

Continuing to FIG. 2C, and taking the isolation structures 210 as removing-stop layers, a portion of the conductive material layer 240 is removed until the surfaces of the isolation structures 210 are exposed, and a plurality of conductive lines 240a is formed on the active regions 220 in a self-aligned manner to electrically connect the devices . In an embodiment, the method to remove the portion of the conductive material layer 240 is, for example, chemical mechanical polishing (CMP) or etching back. And the formed conductive lines 240a are, for example, word lines (WLs) in the memory array. The conductive lines 240a electrically connect the plurality of memory cells (not shown) in the active region 220.

Note that the top surfaces of the isolation structures 210 are much higher than the surface of the substrate 200, and the top surfaces of the isolation structures 210 are higher than the memory cells in the active regions 220. Therefore, during the chemical mechanical polishing process to remove the conductive material layer 240, a polishing pad (not shown) arrives first at the isolation structures 210 and the polishing course is ended. Consequently, the conductive line 240a is formed on each active region 220 in a self-aligned manner without causing damage to the memory cells in the active region 220.

FIG. 2D schematically shows a structure containing self-aligned conductive lines in another embodiment of the present invention. Referring to FIG. 2D, the structure containing self-aligned conductive lines includes, for example, a substrate 200, a plurality of isolation structures 212 and a conductive line 240a.

The isolation structures 212 are located in the substrate 200, and each of the isolation structures 212 has a protrusion 212a protrusive from the surface of the substrate 200. Between two adjacent protrusions 212a, a gap is formed. The adjacent isolation structures 212 define an active region 220 where a plurality of devices are formed (not shown). The conductive lines 240a are located in the gaps and cover the active regions 220. The conductive lines 240a electrically connect a plurality of devices, and the surfaces of the conductive lines 240 are of the same height as top surfaces of the isolation structures 212.

Note that the top surfaces of the isolation structures 212 are much higher than the surface of the substrate 200. In an embodiment, a cross-sectional shape of a isolation structure 212 is, for example, an inverse T. Therefore, the protrusion 212a of the isolation structure 212 can serve as a removing-stop layer during the chemical mechanical polishing process to remove the conductive material layer. Thereby, as a polishing pad arrives at the top surface of the protrusion 212a, the polishing is ended and the self-aligned conductive 240a lines are formed.

In an embodiment of the present invention, the conductive lines 240a are made of, for example, poly silicon or metal. The devices include, for example, a plurality of semiconductor devices, and the semiconductor devices are trench devices, for example.

A further explanation of the above-described method for fabricating the self-aligned word lines can be seen from an application thereof to fabricate a trench device. In the following embodiment, a process to fabricate conductive lines to connect trench devices is described.

### The Second Embodiment

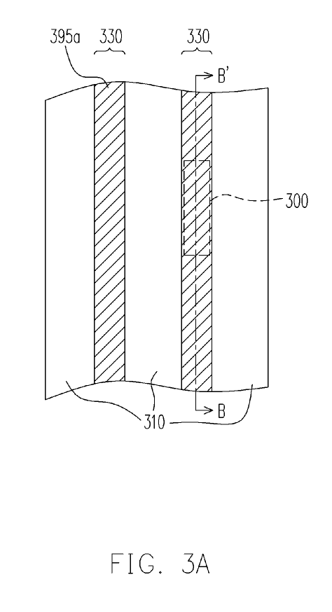

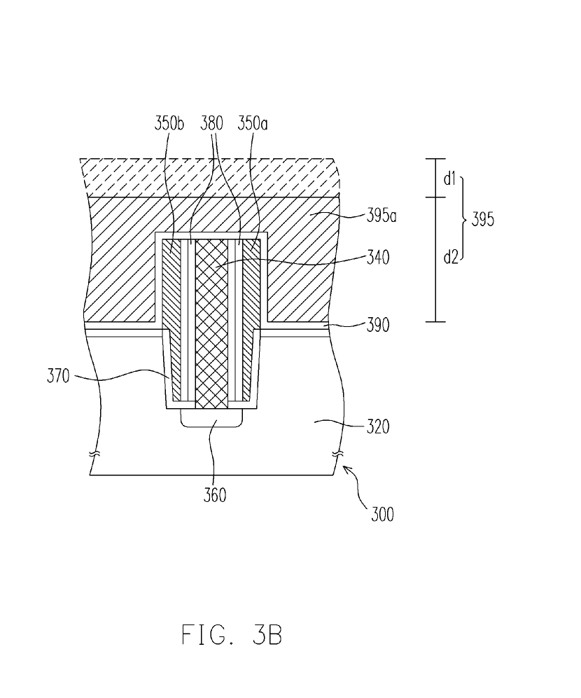

FIG. 3A is a schematic top view of an array containing trench devices. FIG. 3B is a schematic cross-sectional view showing a process of fabricating the word line along line B-B′ in the process for fabricating an array containing trench devices. Please refer to FIGS. 3A and 3B.

As shown in FIGS. 3A and 3B, the substrate 320 is provided. A plurality of isolation structures 310 previously formed in the substrate 320 are protrusive from the surface of the substrate 320. Furthermore, an active region 330 is defined between the adjacent isolation structures 310. In the active region 330, a plurality of trench devices 300 have been formed previously. The method for forming the trench devices 300 is apparent to those skilled in the art, and is omitted in the specification.

Referring to FIG. 3B, in an embodiment of the present invention, the trench device 300 is, for example, a trench flash memory cell, and the trench device 300 includes at least a tunnel oxide layer 370, a control gate 340, two floating gates 350a and 350b, and a dielectric layer 390.

Among these, the tunnel oxide layer 370 is formed on the surface of a trench in the active region 330. The two floating gates 350a and 350b are formed on both sides of the control gate 340. The dielectric layer 390 is formed between the control gate 340 and the two floating gates 350a and 350b, covering them. In an embodiment, the trench device 300 further includes, for example, a doped region 360 formed in the substrate 320. The doped region 360 can be a source/drain region located in the trench device 300. In a device array, the doped region 360 can be a buried bit line for connecting each of the trench devices 300. The control gate 340 is located over the doped region 360. In addition, an inter-gate dielectric layer 380 can be disposed between the control gate 340 and two floating gates 350a and 350b.

Next, the conductive lines (word lines) 395a are fabricated by the method for fabricating the self-aligned conductive lines in the first embodiment.

Namely, a conductive material layer 395 to cover the isolation structures 310 and the active region 330 is formed on the substrate 320. Thereafter, taking the isolation structures 310 as removing-stop layers, a portion of the conductive material layer 395 is removed until the surfaces of the isolation structures 310 are exposed. A conductive line 395a to electrically connect the plurality of the trench devices 300 in the active region 330 is formed. The surface of conductive line 395a is of the same height as the top surfaces of the isolation structures 310.

Referring to FIGS. 3A and 3B for a detailed explanation, we find the isolation structures 310 are in bar layout and are much higher than the substrate 320. The isolation structures 310 are higher than the top surfaces of the trench devices 300 and have a thickness of d2. In the following step, a conductive material layer 395 with a thickness of (d1+d2) is entirely formed on the substrate 320 and covers the isolation structures 310 and the active region 330. In an embodiment, the conductive material layer 395 is made of, for example, poly silicon or metal. The method for forming the conductive material layer 395 is, for example, physical vapor deposition (PVD) or chemical vapor deposition (CVD).

Thereafter, taking the isolation structures 310 as removing-stop layers, a portion of the conductive material layer 395, namely, the portion with thickness of d1 as shown in FIG. 3B, is removed until the surfaces of the isolation structures 310 are exposed. That is, the remaining thickness of the isolation structures 310 is approximately d2. At this point, the conductive lines 395a are formed on the active region 330 in a self-aligned manner to electrically connect the devices. In an embodiment, the method to remove the portion of the conductive material layer 395 is, for example, chemical mechanical polishing (CMP) or etching-back. The formed self-aligned conductive lines 395a serve to electrically connect the plurality of trench devices 300 on the active regions 330.

In an embodiment of the present invention, the structure of a semiconductor device is described as follows. Referring to FIGS. 3A and 3B, the structure of the semiconductor device in the present invention includes a substrate 320, a trench device 300, a plurality of isolation structures 310, and a conductive line 395a.

The isolation structures 310 are located in the substrate 320, and each of the isolation structures 310 includes a protrusion protrusive from the surface of the substrate 320, as shown in FIG. 2D. Between two adjacent protrusions, a gap is formed. In an embodiment of the present invention, the isolation structures 310 are, for example, shallow trench isolation (STI) structures. Between the adjacent isolation structures 310, an active region 330 is defined.

The trench device 300 is located in the active region 330. The trench device 300 includes, for example, a tunnel oxide layer 370, a control gate 340, two floating gates 350a and 350b, and a dielectric layer 390. The tunnel oxide layer 370 is disposed on the surface of a trench in the active region 330. The two floating gates 350a and 350b are disposed on both sides of the control gate 340. The dielectric layer 390 is located between the control gate 340 and the two floating gates 350a and 350b, covering them. In addition, an inter-gate dielectric layer 380 can be disposed between the control gate 340 and the two floating gates 350a and 350b as well. In an embodiment, the trench device 300 further includes, for example, a doped region 360 disposed in the substrate 320. The doped region 360 can be a source/drain region in a trench device 300. The source/drain region is located in the substrate 320 of the trench and below the control gate 360. In a device array, the doped region 360 can be a buried bit line for connecting each of the trench devices 300. The buried bit line is located in the substrate 320 of the trench and below the control gate 340.

The conductive line 395a is located in the gap and covers the active region 330. The conductive line 395a electrically connects a plurality of trench devices 300 and the surface thereof is of the same height as the top surfaces of isolation structures 310. In an embodiment of the present invention, the conductive line 395a is a word line. The method for fabricating the conductive line 395a can refer to the second embodiment hereinabove. Beside, the structure of the trench devices is not limited to the structure as shown in FIG. 3B. For example, the floating gates 350a and 350b of the trench device 300 may have a sharp tip at the top there of next to the conductive line 395a. The other source/drain regions (not shown) are formed in the surface layer of substrate adjacent to the floating gates350a and 350b.

To sum up, the present invention has at least the following advantages.
(1) In the method for fabricating the self-aligned conductive lines of the present invention, the isolation structures have been formed on the substrate previously and are much higher than the substrate. Because the isolation structures serve as removing-stop layers, as the removing is ended, the conductive lines used for connecting the semiconductor devices can be formed in a self-aligned manner.
(2) The method for fabricating the self-aligned conductive lines of the present invention is also suitable for connecting the trench devices fabricated in the trenches.

(3) In the structures containing the self-aligned conductive lines of the present invention, the isolation structures are protrusive from and much higher than the surface of the substrate; therefore, in the removal of the conductive material layer, the isolation structures can serve as removing-stop layers without causing damages to the formed devices in the active region.

(4) The semiconductor devices of the present invention have rib isolation structures much higher than the surface of the substrate; therefore, the active region can be defined between the adjacent isolation structures, and the trench devices can be fabricated in the active region. Because the isolation structures are much higher than the surface of the substrate, the isolation structures can further be used for fabricating the self-aligned conductive lines to electrically connect the trench devices.

(5) The present invention is capable of fabricating the conductive lines with smaller size and higher position accuracy to connect the micro-devices of the semiconductor.

It will be apparent to those skilled in the art that various modifications and variations can be made to the structure of the present invention without departing from the scope or spirit of the invention. In view of the foregoing, it is intended that the specification and examples be considered as exemplary only, with a true scope and spirit of the invention being indicated by the following claims and their equivalents.

What is claimed is:

1. A method for fabricating self-aligned conductive lines, comprising:
providing a substrate in which a plurality of isolation structures have been formed previously, wherein the isolation structures are protrusive from the surface of the substrate, and an active region is defined between the isolation structures, and a plurality of devices is formed in the active region;
forming a conductive material layer on the substrate to cover the isolation structures and the active region; and
removing a portion of the conductive material layer by using the isolation structures as removing-stop layers until surfaces of the isolation structures are exposed, such that a plurality of conductive lines is formed in the active region to electrically connect the devices.

2. The method of claim 1, wherein the material of the conductive material layer comprises poly silicon or metal.

3. The method of claim 1, wherein the method for forming the conductive material layer comprises physical vapor deposition (PVD) or chemical vapor deposition (CVD).

4. The method of claim 1, wherein the method for removing a portion of the conductive material layer comprises chemical mechanical polishing (CMP) or etching back process.

5. The method of claim 1, wherein the conductive lines are word lines (WLs).

6. The method of claim 1, wherein the method for forming the isolation structures comprises shallow trench isolation process.

7. The method of claim 1, wherein the semiconductor devices comprise trench devices.

8. The method of claim 1, wherein each of the trench devices comprising:
a tunnel oxide layer formed on the surface of a trench in the active region;
a control gate;
two floating gates formed on both sides of the control gate; and
a dielectric layer formed between the control gate and the floating gates and covering them.

9. The method of claim 8, wherein each of the trench devices further comprises a buried bit line disposed in the substrate of the trench.

10. The method of claim 9, wherein the control gate is located over the buried bit line.

11. A structure containing self-aligned conductive lines, comprising:
a substrate;
a plurality of isolation structures located in the substrate, and each of the isolation structures having a protrusion protrusive from the surface of the substrate, wherein a gap is formed between the two protrusions, an active region is defined between the adjacent isolation structures, and a plurality of devices are formed in the active region; and
a conductive line located in the gap, covering over the active region to electrically connect the devices, wherein the surface of the conductive line is of the same height as the top surfaces of isolation structures.

12. The structure of claim 11, wherein the material of the conductive material layer comprises poly silicon or metal.

13. The structure of claim 11, wherein the devices comprise a plurality of semiconductor devices.

14. The structure of claim 11, wherein the semiconductor devices comprise trench devices.

15. A semiconductor structure, comprising:
a substrate;
a plurality of isolation structures, located in the substrate, and each of the isolation structures having a protrusion protrusive from the surface of the substrate, a gap is formed between the two protrusions, and an active region is defined between the adjacent isolation structures;
a plurality of trench devices located in the active region and each of the trench devices comprising:
a tunnel oxide layer disposed on the surface of a trench in the active region;
a control gate;
two floating gates disposed on both sides of the control gate;
a dielectric layer located between the control gate and the floating gates and covering them; and
a conductive line, located in the gap, covering over the active region to electrically connect the trench devices, wherein the surface of the conductive line is of the same height as the top surfaces of isolation structures.

16. The semiconductor structure of claim 15, wherein the conductive line is a bit line.

17. The semiconductor structure of claim 15, wherein the isolation structures are shallow trench isolation (STI) structures.

18. The semiconductor structure of claim 15, wherein each of the trench devices further comprises a source/drain region located in the substrate of the trench and located below the control gate.

19. The semiconductor structure of claim 15, wherein each of the trench devices further comprises a buried bit line located in the substrate of the trench and located below the control gate.
